(19) United States
(12) Patent Application Publication
(10) Pub. No.: US 2024/0105670 A1
(43) Pub. Date: Mar. 28, 2024

(54) ELECTRONIC COMPONENT WITH HIGH COPLANARITY AND METHOD OF MANUFACTURING THE SAME

(71) Applicant: CYNTEC CO., LTD., Hsinchu (TW)

(72) Inventor: Chi-Hung Su, Hsinchu (TW)

(73) Assignee: CYNTEC CO., LTD., Hsinchu (TW)

(21) Appl. No.: 17/952,348

(22) Filed: Sep. 26, 2022

(51) Int. Cl. H01L 23/00; H01Q 1/48; H01Q 9/04

(52) U.S. Cl. CPC H01L 24/73; H01L 24/03; H01L 24/05; H01L 24/11; H01L 24/13; H01L 24/27; H01L 24/29; H01Q 1/48; H01Q 9/0407; H01L 24/16; H01L 24/32; H01L 2224/0332; H01L 2224/0363; H01L 2224/05552; H01L 2224/05573; H01L 2224/05639; H01L 2224/05644; H01L 2224/05647; H01L 2224/1132; H01L 2224/1163; H01L 2224/11825; H01L 2224/13012; H01L 2224/13139; H01L 2224/13144; H01L 2224/13147; H01L 2224/1357; H01L 2224/13582; H01L 2224/13609; H01L 2224/13611; H01L 2224/13613; H01L 2224/13616; H01L 2224/13618; H01L 2224/13639; H01L 2224/13647; H01L 2224/13655; H01L 2224/16227; H01L 2224/27462; H01L 2224/2763; H01L 2224/29012; H01L 2224/29034; H01L 2224/29082; H01L 2224/29109; H01L 2224/29111; H01L 2224/29113; H01L 2224/29116; H01L 2224/29118; H01L 2224/29139; H01L 2224/29147; H01L 2224/29155; H01L 2224/32227; H01L 2224/73103; H01L 2924/0132; H01L 2924/014; H01L 2924/1421; H01L 2924/1423

(57) ABSTRACT

An electronic component with high coplanarity, including a body with a functional circuit and a mounting plane, a first electrode with a first area deposited on the mounting plane, and a second electrode with a second area deposited on the mounting plane, wherein the first area is larger than the second area, and the first electrode and the second electrode includes a conductive layer and at least one first plating layer over the conductive layer, and a thickness of the conductive layer of the first electrode is smaller than a thickness of the conductive layer of the second electrode, and a thickness of the first plating layer of the first electrode is larger than a thickness of the first plating layer of the second electrode.

### BACKGROUND OF THE INVENTION

### 1. Field of the Invention

The present invention relates generally to an electronic component and method of manufacturing the same, and more specifically, to an electronic component with high coplanarity between electrodes and method of manufacturing the same.

### 2. Description of the Related Art

In many current high-frequency components, such as antenna or filter, grounding electrode and signal electrode of the component are usually coplanar and aren't connected with each other. That is, they are designedly formed on the same plane and individual to each other. With the fact that the grounding electrode and signal electrode in high-frequency device usually have different planar areas, the aforementioned factors collectively cause conventional phenomenon that plating layers formed on the electrodes in the same electroplating process have quite different thicknesses, and this phenomenon of uneven thickness can't meet strict requirement of coplanarity (within 10 μm) between the grounding electrode and signal electrode of radio frequency (RF) components in high-frequency operation. Accordingly, those of skilled in the art need to develop a method of improving the coplanarity in the electroplating process for high-frequency components.

### SUMMARY OF THE INVENTION

In order to solve the aforementioned problem of uneven thickness for the electrodes of high-frequency components, the present invention hereby provide a novel electronic component design with high coplanarity and method of manufacturing the same, featuring the approach of using conductive layers with different thicknesses respectively for the electrodes with different areas, as well as the approach of cutting the conductive connection between the two electrodes with different areas after electroplating, to attain final plating layers on the conductive layers of the two electrodes with uniform thickness.

One aspect of present invention is to provide an electronic component with high coplanarity, including a body with a functional circuit and a mounting plane, a first electrode with a first area deposited on the mounting plane, and a second electrode with a second area deposited on the mounting plane, wherein the first area is larger than the second area, wherein the first electrode and the second electrode include a conductive layer and at least one first plating layer over the conductive layer, and a thickness of the conductive layer of the first electrode is smaller than a thickness of the conductive layer of the second electrode, and a thickness of the first plating layer of the first electrode is larger than a thickness of the first plating layer of the second electrode.

Another aspect of present invention is to provide an electronic component with high coplanarity, including a body with a functional circuit and a mounting plane, a first electrode on the mounting plane with a first area, a second electrode on the mounting plane with a second area, wherein the first area is larger than the second area, and an groove on the mounting plane connecting the first electrode and the second electrode, wherein the first electrode and the second electrode include a conductive layer and at least one first plating layer over the conductive layer, and a thickness of the conductive layer of the first electrode is substantially equal to a thickness of the conductive layer of the second electrode, and a thickness of the first plating layer of the first electrode is substantially equal to a thickness of the first plating layer of the second electrode.

Still another aspect of present invention is to provide a method of manufacturing an electronic component with high coplanarity, including steps of providing a body with a mounting plane, forming a conductive layer on the mounting plane of the body, wherein the conductive layer includes a first electrode pattern and a second electrode pattern, and a first area of the first electrode pattern is larger than a second area of the second electrode pattern, and a thickness of the first electrode pattern is smaller than a thickness of the second electrode pattern, and simultaneously forming at least one first plating layer over the first electrode pattern and the second electrode pattern of the conductive layer, wherein a thickness of the first plating layer over the first electrode pattern is larger than a thickness of the first plating layer over the second electrode pattern.

Still another aspect of present invention is to provide a method of manufacturing an electronic component with high coplanarity, including steps of providing a body with a mounting plane, forming a conductive layer on the mounting plane of the body, wherein the conductive layer includes a first electrode pattern, a second electrode pattern and a cutting pattern connecting the first electrode pattern and the second electrode pattern, and a first area of the first electrode pattern is larger than a second area of the second electrode pattern, and a thickness of the first electrode pattern is substantially equal to a thickness of the second electrode pattern, forming at least one first plating layers over the conductive layer, wherein a thickness of the first plating layer over the first electrode pattern is substantially equal to a thickness of the first plating layer over the second electrode pattern, and performing a removing process to remove the cutting pattern and the first plating layer on the cutting pattern and leave an groove on the mounting plane that connects the first electrode pattern and the second electrode pattern and electrically disconnects the first electrode pattern and the second electrode pattern.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 is a schematic plan view of electrode patterns in accordance with one embodiment of the present invention;

FIG. 2 to FIG. 5 are schematic cross-sections illustrating a process flow of manufacturing the electronic component with high coplanarity in accordance with one embodiment of the present invention;

FIG. 6 is an enlarged cross-section illustrating the thicknesses of layer structure in the electrodes in accordance with the embodiment of the present invention;

FIG. 7 is an enlarged cross-section illustrating the thicknesses of layer structure in the electrodes in accordance with another embodiment of the present invention;

FIG. 8 to FIG. 9 are schematic plan views illustrating a process flow of manufacturing the electrode patterns in accordance with another embodiment of the present invention;

FIG. 10 and FIG. 11 are enlarged cross-sections illustrating a process flow of manufacturing the electrode patterns with high coplanarity in accordance with another embodiment of the present invention; and

FIG. 12 is a schematic cross-section illustrating the electronic component shown in FIG. 5 mounted on a system PCB in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Dimensions and proportions of certain parts of the drawings may have been shown exaggerated or reduced in size, for the sake of clarity and convenience in the drawings. Other embodiments may be utilized and structural, logical, and electrical changes may be made without departing from the scope of the present invention. The following detailed description, therefore, is not to be taken in a limiting sense, and the scope of the present invention is defined by the appended claims.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature's relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or heterogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

First, please refer to FIG. 1, which is a schematic plan view of electrode patterns in accordance with one embodiment of the present invention. The electronic component of present invention includes a first electrode 100 with a first area and a second electrode 200 with a second area smaller than the first area. The electronic component may be a high-frequency component like antenna, filter (low pass filter or band pass filter), diplexer, or triplexer, with the larger first electrode 100 as a grounding electrode and the smaller second electrode 200 as a signal electrode. The first electrode 100 and second electrode 200 are separated and electrically insulated by a spacing S (within 200 μm), in order to provide sufficient tolerance for the misalignment in screen printing process for forming electrode patterns.

The electrodes of present invention are planar electrodes designed in the type of electrode, with its electrical planar transmission line being fabricated on the same plane and its top plane preferably having the same height. This type of electrodes is suitable to be applied in modern millimeter wave (mmWave) communication system since it may be easily fabricated using photolithography, screen printing or plating technology and be provided with good properties like higher circuit density, smaller volume and light weight, and it may also be built into monolithic integrated circuits, like RFIC or MMIC.

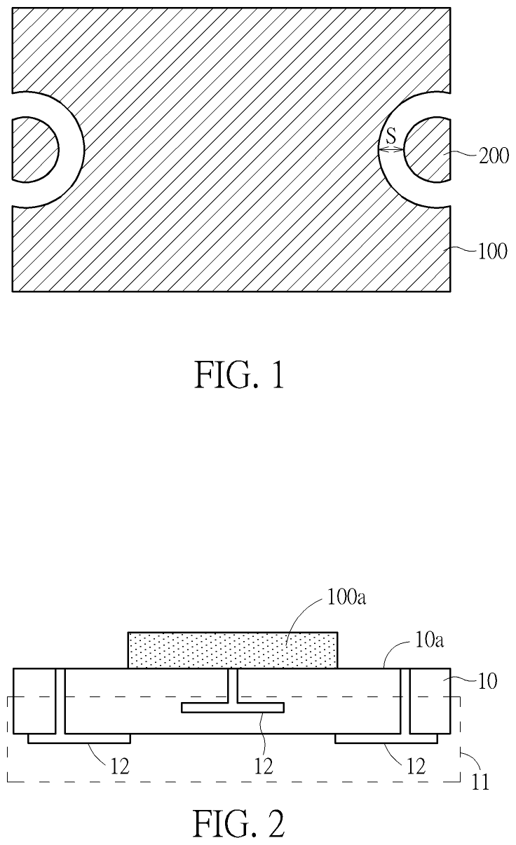

Please refer to FIG. 2 to FIG. 5, which are schematic cross-sections illustrating a process flow of manufacturing the electronic component with high coplanarity in accordance with one embodiment of the present invention. The following embodiment will describe the electrode structure of present invention in cross-sectional views in order to provide a better understanding for the essential features of present invention.

First, in FIG. 2, provide a body 10 to serve as a base for the electronic component of present invention. The body 10 may be a PCB or ceramic substrate, for example, an aluminum oxide (Al₂O₃) ceramic substrate with high Q value, high dielectric constant and low loss, suitable as a substrate for coplanar waveguide filter or antenna. The ceramic-based body 10 may be fabricated by using low temperature co-fired ceramic (LTCC) technology to integrate other electronic components, circuits or modules in its multilayer structure and still provide excellent dielectric property for high frequency component. For example, the body 10 may be multilayer antenna 11 having radiation elements 12 formed with functional circuits integrated therein. In other embodiment, the functional circuits may be low pass filter, band pass filter, diplexer or triplexer integrated therein. In the embodiment of present invention, the body 10 is provided with a mounting plane 10a for forming electrodes and mounting onto a main board like the PCB board in a 5G cell phone, through surface mounting technology. In other embodiment, the functional circuits 12 may also be fabricated on the surface of body 10 after the electrodes are formed, depending on the design of electronic component.

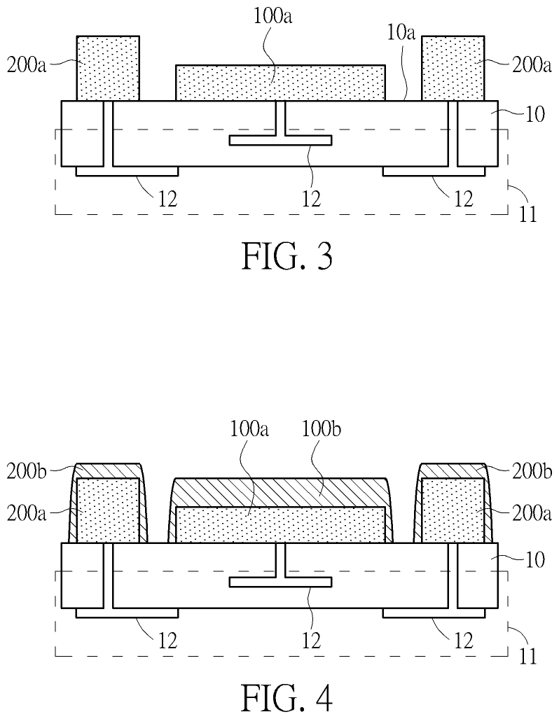

Refer still to FIG. 2 to FIG. 3. A conductive layer 100a of the first electrode 100 with a first electrode pattern is first formed on the mounting plane 10a of body 10. In the embodiment, the first electrode pattern is the pattern of first electrode 100 in FIG. 1. The material of conductive layer 100a, 200a may be silver (Ag), copper (Cu), gold (Au), a combination thereof or an alloy thereof. For example, in preferred embodiment, the conductive layer 100a, 200a is conductive silver paste with good electrical conductivity to ceramic or glass-based substrate, and is formed through screen printing on the body 10 and sintering process.

Refer next to FIG. 3. After the conductive layer 100a of the first electrode 100 is formed, another conductive layer 200a of the second electrode 200 with second electrode pattern is then formed on the mounting plane 10a of body 10. In the embodiment, the second electrode pattern is the pattern of second electrode 200 in FIG. 1. Similarly, the material of conductive layer 200a of the second electrode 200 may be silver (Ag), copper (Cu), gold (Au), a combination thereof or an alloy thereof, formed on the body 10 through another screen printing process and sintering process. The material of the conductive layer 200a of the second electrode 200 and the conductive layer 100a of the first electrode 100 are preferably the same. In the embodiment of present invention, the thickness of the conductive layer 100a of the first electrode 100 is designedly smaller than the thickness of the conductive layer 200a of the second electrode 200. This is why the conductive layer 100a of the first electrode 100 and the conductive layer 200a of the second electrode 200 in the embodiment have to be formed in two screen printing steps using screens or emulsions between the screens and the mounting plane 10a of body 10 with different thicknesses. In some embodiment, the two conductive layers 100a, 200a may also be formed using the same screen with different shielding patterns sequentially (time-division). This approach may help to prevent misalignment in the two screen printing steps. In other embodiment, the aforementioned conductive layer 100a, 200a may also be patterned through photolithography process. The relation between the areas and thicknesses of the conductive layer 100a of the first electrode 100 and conductive layer 200a of the second electrode 200 will be described in later embodiment.

It should be noted that in the embodiment of present invention, the conductive layer 100a of the first electrode 100 and the conductive layer 200a of the second electrode 200 are formed on the mounting plane 10a with the same base level (coplanar design), and the conductive layer (ex. grounding electrode) 100a is electrically connected to a ground terminal (not shown) of the functional circuit formed in or on the body 10, and the conductive layer (ex. signal electrode) 200a is electrically connected to a signal terminal (not shown) of the functional circuit formed in or on the body 10. After both of the conductive layers 100a, 200a are formed on the body 10, the two paste patterns are dried and sintered into solid conductive patterns. These two patterns will function as a conductive layer in following electroplating process and define the patterns of electrodes to be formed.

Refer next to FIG. 4. After the conductive layer 100a of the first electrode 100 and conductive layer 200a of the second electrode 200 are formed, a first electroplating process, such as barrel plating, is then performed to form a second plating layer 100b of the first electrode 100 and a second plating layer 200b of the second electrode 200 simultaneously and respectively on the conductive layer 100a of the first electrode 100 and the conductive layer 200a of the second electrode 200. The material of second plating layer 100b, 200b may be nickel (Ni), zinc-nickel (Zn—Ni), nickel alloy, a combination thereof or an alloy thereof. It should be noted that, as shown in FIG. 4, the thickness of second plating layer 100b of the first electrode 100 is larger than the thickness of second plating layer 200b of the second electrode 200 in the embodiment. This is because the planar area of the conductive layer 100a of the first electrode 100 under the second plating layer 100b is larger than the planar area of the conductive layer 200a of the second electrode 200 under the second plating layer 200b. Higher potential difference in the area of the conductive layer 100a of the first electrode 100 may result faster electro-deposition speed.

In conventional skill, the conductive layers used in electroplating process usually have the same thickness since they are formed in the same screen printing step. This approach may result in relatively thicker plating layer being formed on the conductive layer with larger area (like the conductive layer 100a) and relatively thinner plating layer being formed on the conductive layer with smaller area (like the conductive layer 200a) because larger area usually has higher electro-deposition speed and smaller area has lower electro-deposition speed, so that the top surfaces of final resulting electrodes on different electrodes would not have the same height. This height difference may not meet strict requirement of coplanarity (<10 μm) between the grounding electrode and signal electrode for radio frequency (RF) components in high-frequency operation.

In order to compensate the aforementioned thickness difference of resulting plating layers in electroplating process, in the embodiment of present invention, the conductive layer 100a of the first electrode 100 and the conductive layer 200a of the second electrode 200 are formed designedly with different thicknesses. In electroplating mechanism, the electro-deposition speed is generally proportional to the area of predefined conductive layer, and electro-deposition speed is inversely proportional to resistivity of predefined conductive layer. The larger area of the predefined conductive layer, the thicker the plating layer to be formed thereon in the electroplating process. Accordingly, in the embodiment of present invention, since the conductive layer 100a of the first electrode 100 having larger planar area is inherently provided with higher electro-deposition speed in electroplating process, it is formed with smaller thickness of the conductive layer 100a of the first electrode 100 to compensate its higher electro-deposition speed in a condition that the resistivity is the same or close, for example, with difference smaller than 30%. In addition, smaller vertical thickness of the conductive layer 100a of the first electrode 100 may also leave larger vertical space for thicker second plating layer 100b to be formed thereon. Conversely, since the conductive layer 200a of the second electrode 200 having smaller planar area is inherently provided with lower electro-deposition speed in electroplating process, it is formed with larger thickness of the conductive layer 200a of the second electrode 200 to compensate its lower electro-deposition speed in a condition that the resistivity is the same or close, for example, with difference smaller than 30%. In addition, larger vertical thickness of the conductive layer 200a of the second electrode 200 may leave smaller vertical space for thinner second plating layer 200b to be formed thereon. In this way, the resulting plating layers on the two electrode patterns may have better coplanarity.

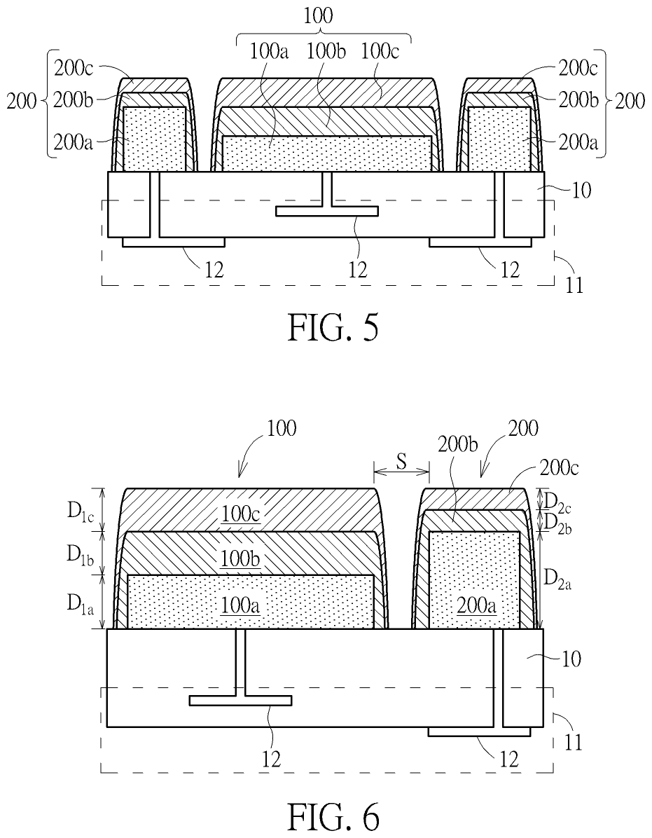

Refer next to FIG. 5. After the second plating layer 100b of the first electrode 100 and second plating layer 200b of the second electrode 200 are formed, a second electroplating process is then performed to form a first plating layer 100c of the first electrode 100 and a first plating layer 200c of the second electrode 200 simultaneously and respectively on the second plating layer 100b of the first electrode 100 and second plating layer 200b of the second electrode 200. The material of first plating layer 100c, 200c may be solder, for example, that may be tin (Sn), tin-silver (Sn—Ag), tin-silver-copper (Sn—Ag—Cu), tin-lead (Sn—Pb), tin-bismuth (Sn—Bi), tin-indium (Sn—In), tin alloy, a combination thereof or an alloy thereof, with its soldering temperature or melting temperature preferably lower than melting temperature of the ones of conductive layers 100a, 200a or/and second plating layers 100b, 200b. Similarly, it should be noted that as shown in FIG. 5, the thickness of first plating layer 100c of the first electrode 100 formed on the second plating layer 100b is larger than the thickness of first plating layer 200c of the second electrode 200 formed on the second plating layer 200b since the two second plating layers have different planar areas, and the difference of electro-deposition speeds for the first plating layer 100c of the first electrode 100 and first plating layer 200c of the second electrode 200 are also compensated by the different thicknesses of the conductive layer 100a of the first electrode 100 and the conductive layer 200a of the second electrode 200 like the ones for second plating layer 100b and second plating layer 200b.

Refer still to FIG. 5. In the embodiment, the first plating layer 100c, second plating layer 100b and conductive layer 100a constitute collectively the first electrode 100 of present invention, and the first plating layer 200c, second plating layer 200b and conductive layer 200a constitute collectively the second electrode 200 of present invention, wherein the Ni-based second plating layer 100b and second plating layer 200b may function as a barrier layer to prevent Sn-based first plating layer 100c and first plating layer 200c reacting with Ag-based conductive layers 100a, 200a to form Sn—Ag alloy at high soldering temperature or high operation temperature, which may increase the resistance and decrease the reliability of the electrodes 100, 200. Furthermore, through the aforementioned approach of providing predefined conductive layers with different thickness, the height difference of resulting plating layers on electrodes with different planar areas may be tuned and compensated to reach optimally the same height, which may meet strict coplanarity requirement for high-end RF components and increase their performance.

In other embodiment, different electro-deposition speeds may also be compensated by using paste materials with different resistivities for the predefined conductive layers. For example, for the conductive layer with larger area, conductive paste with higher resistivity (ex. paste with silver and ceramic filler or paste with silver and silicon oxide, wherein percentage composition of silver is between 50%-85%) may be used in screen printing process to compensate its higher electro-deposition speed. Conversely, for the conductive layer with smaller area, conductive paste with lower resistivity (ex. percentage composition of silver >85%) may be used in screen printing process to compensate its lower electro-deposition speed. This approach needs not to tune the thicknesses of different conductive layers to reach optimal coplanarity, but still needs two screen printing steps to form the conductive layers with different conductive or/and resistivity materials.

The final product of the electronic component in the present invention may later be mounted onto a main board like the PCB board used in a 5G cell phone through surface mounting technology. For example, solder material may be used between the plating layers 100c, 200c and the copper pads of PCB board to electrically connect the circuits within the electronic component and the PCB board to function the device.

Please refer to FIG. 6, which is an enlarged cross-section illustrating the thicknesses of layer structure in the electrodes in accordance with the embodiment of the present invention. In the present invention, the thicknesses of final resulting first electrode 100 and second electrode 200 are preferably the same, thus they may have the same height and optimal coplanarity. That is, the summation of thicknesses (D₁ₐ+D_{1b}+D_{1c}) of conductive layer 100a, second plating layer 100b and first plating layer 100c is preferably equal to the summation of thicknesses (D₂ₐ+D_{2b}+D_{2c}) of conductive layer 200a, second plating layer 200b and first plating layer 200c. The first electrode 100 and the second electrode 200 have the same number of layer structures. This feature may be reached by providing conductive layer 100a of the first electrode 100 having larger planar area with smaller thickness D₁ₐ and providing conductive layer 200a of the second electrode 200 having smaller planar area with larger thickness D₂ₐ (D₁ₐ<D₂ₐ). The thicknesses D_{1b}, D_{1c} of resulting plating layers 100b, 100c are inherently larger than the thicknesses D_{2b}, D_{2c} of resulting plating layers 200b, 200c (D_{1b}>D_{2b}, D_{1c}>D_{2c}) since the underlying conductive layer 100a of the first electrode 100 has larger planar area than the one of conductive layer 200a of the second electrode 200. Nevertheless, in the embodiment of present invention, these plating thickness D_{1b}, D_{1c}, D_{2b} and D_{2c} are tuned and compensated by the different thickness of predefined conductive layers 100a, 200a, thus the final electrode products 100, 200 may reach the same height and optimal coplanarity (height difference <10 μm). In addition, the spacing between the first electrode 100 and second electrode 200 is preferably within 200 μm to provide better electrical insulation and misalignment tolerance.

In one embodiment, resistivity of the conductive layer 100a of the first electrode 100 is larger than resistivity of the conductive layer 200a of the second electrode 200. The thickness (D_{1b}, D_{1c}, D_{2b}, D_{2c}) of plating layers 100b, 100c may be controlled through adjusting the difference between the two resistivities to make D₁ₐ+D_{1b}+D_{1c}=D₂ₐ+D_{2b}+D_{2c}, for example in a condition like (D₁ₐ<D₂ₐ) and (D_{1b}>D_{2b}, D_{1c}>D_{2c}) as shown in the figure. In some embodiments, even conductive layers 100a, 200a with the same thickness (D₁ₐ=D_{1b}) are used, the relation of D_{1b}=D_{2b}, D_{1c}=D_{2c} may still be achieved through adjusting the ratio of the two resistivities.

Please refer now to FIG. 7, which is an enlarged cross-section illustrating the thicknesses of layer structure in the electrodes in accordance with another embodiment of the present invention. When the material of conductive layers 100a, 200a is conductive metal with thermostability like copper (Cu) or when the electronic component has no strict requirement for low resistivity, it is unnecessary to form Ni-based second plating layer 100b, 200b as barrier layers to prevent the alloy reaction between Sn-based third and fourth plating layers 100c, 200c and the conductive layer 100a, 200a at high soldering temperature or high operating temperature. In this condition, similarly, as shown in FIG. 7, the thicknesses of final resulting first electrode 100 and second electrode 200 are preferably the same. That is, the summation of thicknesses (D₁ₐ+D_{1c}) of conductive layer 100a and first plating layer 100c of the first electrode 100 is preferably equal to the summation of thicknesses (D₂ₐ+D_{2c}) of conductive layer 200a and first plating layer 200c of the second electrode 200. This feature may be reached by providing conductive layer 100a of the first electrode 100 having larger planar area with smaller thickness D₁ₐ and providing conductive layer 200a of the second electrode 200 having smaller planar area with larger thickness D₂ₐ. The thickness D_{1c} of resulting first plating layer 100c are inherently larger than the thickness D_{2c} of resulting first plating layer 200c (D_{1c}>D_{2c}) since the underlying conductive layer 100a of the first electrode 100 has larger planar area than the one of conductive layers 200a of the second electrode 200. Nevertheless, in the embodiment of present invention, these first plating thickness D_{1c} and D_{2c} are tuned and compensated by the different thicknesses of predefined conductive layers 100a, 200a, thus the final electrode products 100, 200 may reach the same height and optimal coplanarity (height difference <10 μm). Similarly, the spacing between the first electrode 100 and second electrode 200 is preferably within 200 μm to provide better electrical insulation and misalignment tolerance.

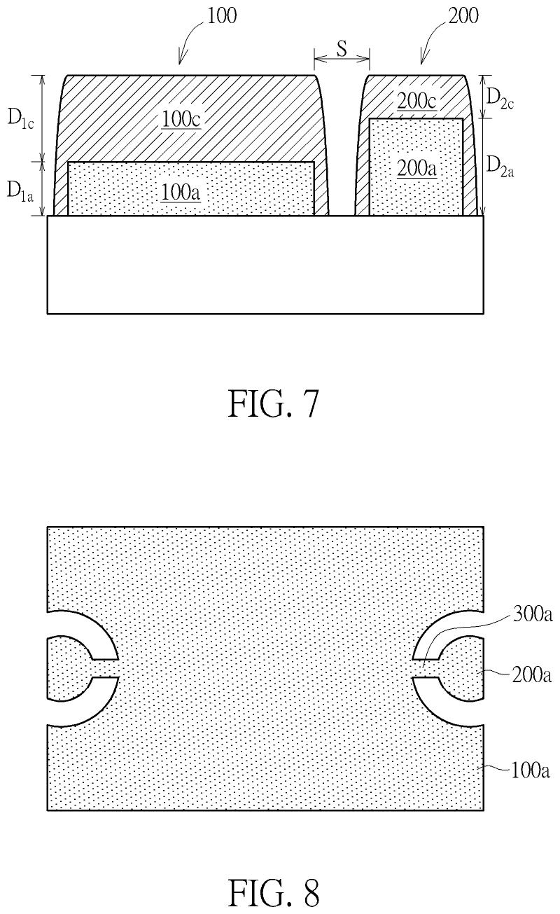

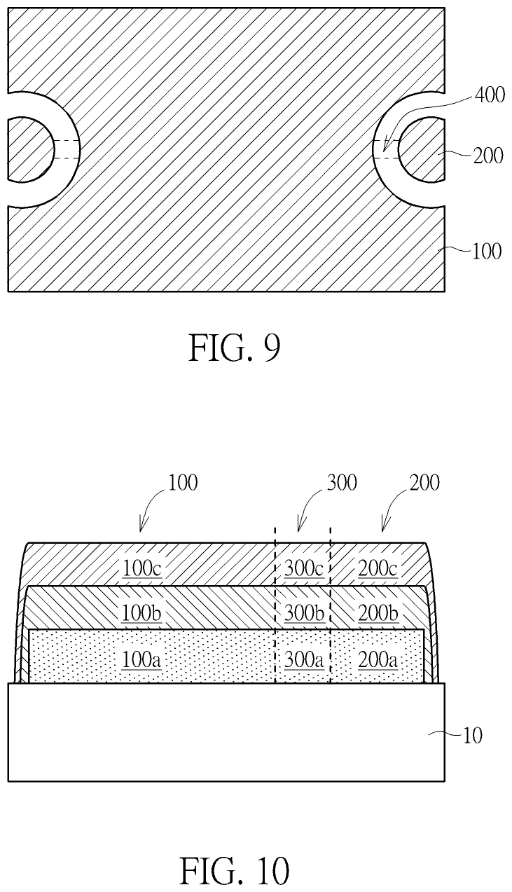

Please refer now to FIG. 8 and FIG. 9, which are schematic plan views of electrode patterns illustrating another method of manufacturing the electronic component. In FIG. 8, the electronic component of present invention includes a conductive layer 100a of the first electrode 100 having a first electrode pattern with a first area, conductive layers 200a of the second electrode 200 having second electrode patterns with a second area smaller than the first area and conductive layers 300a of cutting structure having cutting patterns connecting the first electrode 100a and second electrode 200a. The material of conductive layers 100a, 200a and 300a may be silver (Ag), copper (Cu), gold (Au), a combination thereof or an alloy thereof, which may be formed through screen printing on a body or substrate. Please note that in this embodiment, the thicknesses of conductive layer 100a of the first electrode 100, conductive layer 200a of the second electrode 200 and conductive layers 300a of cutting structure may be the same. That is, they can be formed in the same screen printing, drying and sintering processes.

After the conductive layers 100a, 200a and 300a are formed, as shown in FIG. 10, the same electroplating processes may then be performed to form Ni-based second plating layer and Sn-based first plating layer simultaneously on the conductive layers 100a of the first electrode 100, conductive layers 200a of the second electrode 200 and conductive layers 300a of cutting structure 300, thereby forming the first electrode, cutting structure 300 and the second electrode. In this embodiment, since the conductive layer 100a of the first electrode 100 and the conductive layers 200a of the second electrode 200 are electrically connected by the conductive layers 300a of cutting structure 300 and all of them are formed with the same thickness, they will have the same conductive plane during the electroplating processes and, therefore, the Ni-based second plating layer and Sn-based first plating layer formed on these different patterns of conductive layers 100a, 200a, 300a may have substantially the same thickness.

Please refer to FIG. 9. After the Ni-based second plating layer and Sn-based first plating layer are formed on the conductive layers, the cutting structures and the plating layers thereon are removed to electrically disconnect the first electrode 100 and second electrodes 200. In the embodiment, the cutting structure may be removed through laser engraving, and an engraving mark (or groove) 400 will be left on the substrate between the first electrode 100 and second electrode 200 after the removing step.

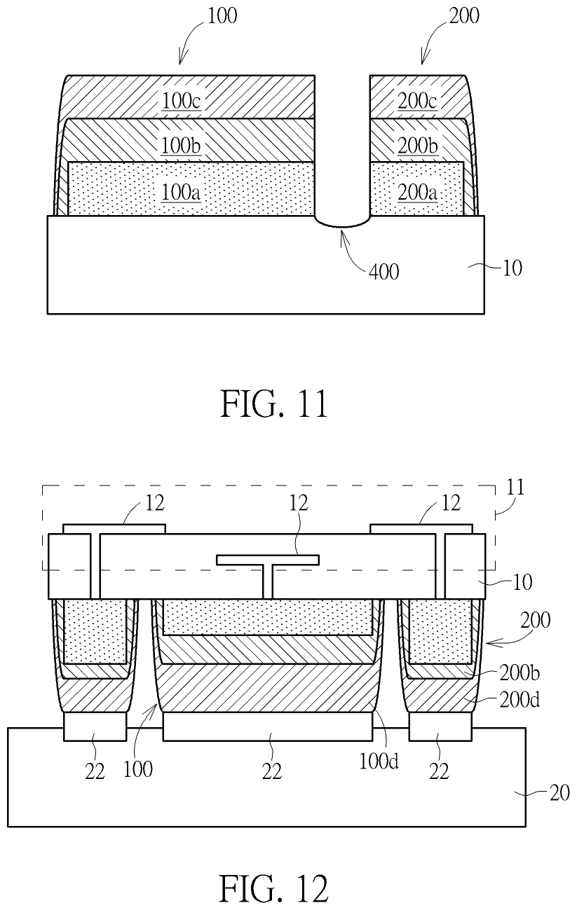

Please refer to FIG. 11, which is an enlarged cross-section of the electronic component with high coplanarity in accordance with this embodiment of the present invention. As shown in the FIG. 11, the first electrode 100 and the second electrode 200 have the same number of layer structures, including conductive layers 100a, 200a, Ni-based second plating layer 100b, 200b and Sn-based first plating layer 100c, 200c, sequentially on the body 10. What difference in this embodiment is, since these plating layer are formed in the same electroplating process under the same conductive plane while the conductive layer 100a of the first electrode 100 and conductive layer 200a of the second electrode 200 are still electrically connected, they have the same thickness, and the total thicknesses of resulting first electrode 100 and second electrode 200 are substantially the same, so they may reach the same height and optimal coplanarity. An engraving mark (or groove) 400 is formed on the body 10 between the first electrode 100 and second electrode 200.

Please refer to FIG. 12, which is a schematic cross-section illustrating the electronic component as shown in FIG. 5 mounted on a system PCB in accordance with one embodiment of the present invention. As shown in FIG. 12, after the electronic component with the first electrode 100 and the second electrode 200 is completed, the electronic component may be further mounted on a PCB 20 (ex. a system PCB in an electronic device) through a soldering process. The solder (i.e. the Sn-based first plating layers 100c, 200c) on the electronic component of present invention and the Sn-based solder (not shown) on the PCB 20 will be fused together through reflow or wave soldering in the process to form common solders 100d, 200d that connecting the first electrode 100 and second electrode 200 respectively with the corresponding solder pads 22 on the PCB 20. The PCB 20 may be provided with solder pads 22 having leveled top surfaces, and the Sn-based solder applied or plated on the solder pads 22 may have different thicknesses in order to match the Sn-based first plating layers 100c, 200c on the first electrode 100 and second electrode 200 connected therewith. The total thickness of the first electrode 100 and the resulted common solder 100d formed between the solder pad 22 and the first electrode 100 would be the same as the total thickness of the second electrode 200 and the resulted common solder 200d formed between the solder pad 22 and the second electrode 200, with a thickness difference preferably smaller than 10 μm plus solder tolerance (about 5 μm) (height difference <15 μm).

Similarly, regarding the embodiment of FIG. 7 that the first electrode 100 and the second electrode 200 are not be provided with second plating layers 100b and 200b, the solders (i.e. the Sn-based first plating layers 100c, 200c) on the electronic component and the Sn-based solders on a PCB may be fused together in the same way to form common solders like the ones shown in FIG. 12. Redundant description will not be herein repeated.

The novel electronic component design of present invention as described above, with high coplanarity for the electrodes having different areas, may attain final plating layers or common solders after soldered on a PCB with uniform thickness, to provide better solderability and prevent signal attenuation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic component with high coplanarity, comprising:
a body with a functional circuit and a mounting plane;
a first electrode with a first area deposited on said mounting plane; and
a second electrode with a second area deposited on said mounting plane, wherein said first area is larger than said second area;
wherein said first electrode and said second electrode comprise a conductive layer and at least one first plating layer over said conductive layer, and a thickness of said conductive layer of said first electrode is smaller than a thickness of said conductive layer of said second electrode, and a thickness of said first plating layer of said first electrode is larger than a thickness of said first plating layer of said second electrode.

2. The electronic component with high coplanarity of claim 1, further comprising a second plating layer between said first plating layer and said conductive layer, wherein a thickness of said second plating layer of said first electrode is larger than a thickness of said second plating layer of said second electrode.

3. The electronic component with high coplanarity of claim 2, wherein a material of said second plating layer comprise nickel (Ni), zinc-nickel (Zn—Ni), nickel alloy, a combination thereof or an alloy thereof, and a material of said first plating layer comprises tin (Sn), tin-silver (Sn—Ag), tin-silver-copper (Sn—Ag—Cu), tin-lead (Sn—Pb), tin-bismuth (Sn—Bi), tin-indium (Sn—In), a combination thereof or an alloy thereof.

4. The electronic component with high coplanarity of claim 1, wherein a material of said conductive layer comprises silver, copper, gold, a combination thereof or an alloy thereof.

5. The electronic component with high coplanarity of claim 1, wherein said conductive layer is formed on said mounting plane with the same base level.

6. The electronic component with high coplanarity of claim 1, wherein a thickness difference between said first electrode and said second electrode is within 10 μm.

7. The electronic component with high coplanarity of claim 1, wherein said first electrode is a grounding electrode electrically connected to a ground terminal of said functional circuit, and said second electrode is a signal electrode electrically connected to a signal terminal of said functional circuit.

8. The electronic component with high coplanarity of claim 1, wherein said functional circuit comprises low pass filter, band pass filter, diplexer, triplexer or antenna.

9. The electronic component with high coplanarity of claim 1, wherein said body further comprises a substrate, and said mounting plane is a plane of said substrate, and said functional circuit is formed in said substrate.

10. The electronic component with high coplanarity of claim 9, wherein said substrate is multilayer structure.

11. The electronic component with high coplanarity of claim 1, wherein said first electrode and said second electrode have the same number of layer structures.

12. The electronic component with high coplanarity of claim 1, wherein a spacing between said first electrode and said second electrode is within 200 μm.

13. The electronic component with high coplanarity of claim 1, resistivity of said conductive layer of said first electrode is larger than resistivity of said conductive layer of said second electrode.

14. An electronic component with high coplanarity, comprising:
a body with a functional circuit and a mounting plane;
a first electrode on said mounting plane with a first area;
a second electrode on said mounting plane with a second area, wherein said first area is larger than said second area; and
a groove on said mounting plane connecting said first electrode and said second electrode;
wherein said first electrode and said second electrode comprise a conductive layer and at least one first plating layer over said conductive layer, and a thickness of said conductive layer of said first electrode is substantially equal to a thickness of said conductive layer of said second electrode, and a thickness of said first plating layer of said first electrode is substantially equal to a thickness of said first plating layer of said second electrode.

15. The electronic component with high coplanarity of claim 14, further comprising a second plating layer between said first plating layer and said conductive layer, wherein a thickness of said second plating layer of said first electrode is substantially equal to a thickness of said second plating layer of said second electrode.

16. The electronic component with high coplanarity of claim 14, wherein said conductive layer is formed on said mounting plane with the same base level.

17. The electronic component with high coplanarity of claim 14, wherein a thickness difference between said first electrode and said second electrode is within 10 μm.

18. The electronic component with high coplanarity of claim 14, wherein said first electrode is a grounding electrode electrically connected to a ground terminal of said functional circuit, and said second electrode is a signal electrode electrically connected to a signal terminal of said functional circuit.

19. The electronic component with high coplanarity of claim 14, wherein said first electrode and said second electrode have the same number of layer structures.

20. The electronic component with high coplanarity of claim 14, wherein a spacing between said first electrode and said second electrode is within 200 μm.

21. A method of manufacturing an electronic component with high coplanarity, comprising:
providing a body with a mounting plane;
forming a conductive layer on said mounting plane of said body, wherein said conductive layer comprises a first electrode pattern and a second electrode pattern, and a first area of said first electrode pattern is larger than a second area of said second electrode pattern, and a thickness of said first electrode pattern is smaller than a thickness of said second electrode pattern; and
simultaneously forming at least one first plating layer over said first electrode pattern and said second electrode pattern of said conductive layer, wherein a thickness of said first plating layer over said first electrode pattern is larger than a thickness of said first plating layer over said second electrode pattern.

22. The method of manufacturing an electronic component with high coplanarity of claim 21, wherein forming said conductive layer on said mounting plane comprises:
performing a first screen printing process to form said first electrode pattern of said conductive layer; and
performing a second screen printing process to form said second electrode pattern of said conductive layer.

23. The method of manufacturing an electronic component with high coplanarity of claim 21, wherein forming said conductive layer on said mounting plane comprises performing a photolithography process to pattern a conductive material layer into said first electrode pattern and said second electrode pattern of said conductive layer.

24. The method of manufacturing an electronic component with high coplanarity of claim 21, further comprising simultaneously forming a second plating layer over said first electrode pattern and said second electrode pattern of said conductive layer before said first plating layer is formed.

25. The method of manufacturing an electronic component with high coplanarity of claim 21, wherein said conductive layer is formed on said mounting plane with the same base level.
